(19) United States
(12) Patent Application Publication
(10) Pub. No.: US 2016/0079106 A1
(43) Pub. Date: Mar. 17, 2016

(54) SEMICONDUCTOR MANUFACTURING APPARATUS, CONTROL METHOD OF ELECTROSTATIC CHUCK, AND ELECTROSTATIC CHUCK DEVICE

(71) Applicant: Kabushiki Kaisha Toshiba, Minato-ku (JP)

(72) Inventor: Masakatsu TAKEUCHI, Obu (JP)

(73) Assignee: Kabushiki Kaisha Toshiba, Minato-ku (JP)

(21) Appl. No.: 14/610,014

(22) Filed: Jan. 30, 2015

(30) Foreign Application Priority Data
Sep. 17, 2014 (JP) 2014-188397

(51) Int. Cl. H01L 21/683; H01L 21/67

(52) U.S. Cl. CPC H01L 21/6833; H01L 21/67248

(57) ABSTRACT

According to one embodiment, a semiconductor manufacturing apparatus comprises an electrostatic chuck and a control unit. The electrostatic chuck includes an electrode. The electrode generates electrostatic force. A work is mounted onto the electrostatic chuck. The work is attracted and stuck to the electrostatic chuck by the electrostatic force. The control unit controls a voltage supplied to the electrode. The control unit adjusts the voltage according to change in attractive force on the work to the electrostatic chuck associated with mounting works onto the electrostatic chuck and processing the works.

### CROSS-REFERENCE TO RELATED APPLICATIONS

This application is based upon and claims the benefit of priority from Japanese Patent Application No. 2014-188397, filed on Sep. 17, 2014; the entire contents of which are incorporated herein by reference.

### FIELD

Embodiments described herein relate generally to a semiconductor manufacturing apparatus, a control method of an electrostatic chuck, and an electrostatic chuck device.

### BACKGROUND

Electrostatic chucks are used to hold works in semiconductor manufacturing apparatuses. The work is attracted and stuck by electrostatic force to a surface of the electrostatic chuck. In the semiconductor manufacturing apparatus, transferring in a work and transferring out the work after processing are repeated. On the electrostatic chuck, mounting a work and lifting up the work are repeated. As a number of processed works in the semiconductor manufacturing apparatus increases, a wear of the electrostatic chuck due to friction with works gradually progresses.

As the wear of the electrostatic chuck progresses, a distance between the work mounted on the electrostatic chuck and an electrode that generates electrostatic force becomes shorter. As the distance between the work and the electrode decreases, excessive electrostatic force starts to be exerted on the work. The excessive electrostatic force being exerted on the work may result in damage to works. Because of the excessive electrostatic force, it may be difficult to take up the work from the electrostatic chuck. Accordingly, the electrostatic chuck is replaced with a new one when the electrostatic force has increased to a certain level. With semiconductor manufacturing apparatuses, it is desired to be able to reduce the frequency of replacement of the electrostatic chuck by delaying the coming of the time at which to replace the electrostatic chuck.

### BRIEF DESCRIPTION OF THE DRAWINGS

FIG. 1 is a diagram showing schematically the configuration of a semiconductor manufacturing apparatus of a first embodiment;

FIG. 2 is a side view showing schematically the configuration of a dielectric and a pad shown in FIG. 1;

FIG. 3 is a diagram showing, in enlarged view, the upper surface and part adjacent thereto of a pillar-shaped body shown in FIG. 2;

FIG. 4 is a graph showing the relation between attractive force and the number of processed wafers in the first embodiment;

FIG. 5 is a graph showing the relation between the amount of change in the temperature and the number of processed wafers and the relation between the voltage and the number of processed wafers in the first embodiment; and

FIG. 6 is a diagram showing schematically the configuration of a semiconductor manufacturing apparatus of a third embodiment.

### DETAILED DESCRIPTION

In general, according to one embodiment, a semiconductor manufacturing apparatus comprises an electrostatic chuck and a control unit. The electrostatic chuck includes an electrode. The electrode generates electrostatic force. A work is mounted onto the electrostatic chuck. The work is attracted and stuck to the electrostatic chuck by the electrostatic force. The control unit controls a voltage supplied to the electrode. The control unit adjusts the voltage according to change in attractive force on the work to the electrostatic chuck associated with mounting works onto the electrostatic chuck and processing the works.

Exemplary embodiments of semiconductor manufacturing apparatuses, control methods of an electrostatic chuck, and electrostatic chuck devices will be explained below in detail with reference to the accompanying drawings. The present invention is not limited to the following embodiments.

### First Embodiment

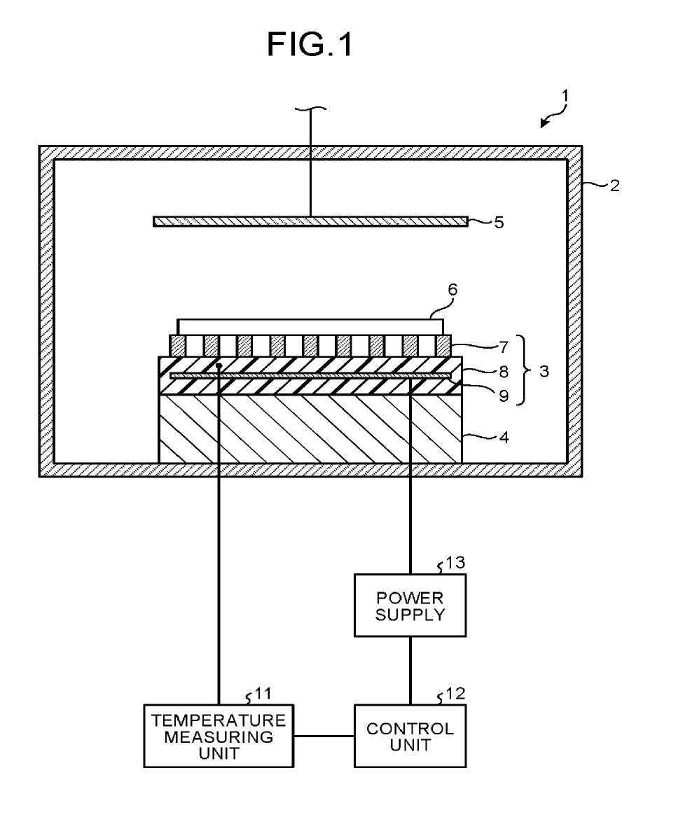

FIG. 1 is a diagram showing schematically the configuration of a semiconductor manufacturing apparatus of the first embodiment. A plasma processing apparatus 1 that is the semiconductor manufacturing apparatus executes plasma processing on a wafer 6 that is a work. The plasma processing apparatus 1 is an etching apparatus, a CVD apparatus, a sputter apparatus, or the like. The plasma processing apparatus 1 is used in forming a thin film or a pattern over the wafer 6.

The plasma processing apparatus 1 comprises a vacuum chamber 2, an electrostatic chuck 3, a mount 4, and an upper electrode 5. The vacuum chamber 2 forms an enclosed space where plasma processing is performed. A process gas flows into the vacuum chamber 2. The pressure inside the vacuum chamber 2 is adjusted to be a pressure at which electrical discharge can occur. The configuration for process gas flowing in and being discharged and the configuration for pressure adjustment are omitted from the figure.

The mount 4 is placed in the vacuum chamber 2. The electrostatic chuck 3 is provided on the upper surface of the mount 4. The mount 4 horizontally supports the wafer 6 on the electrostatic chuck 3. The mount 4 functions as a lower electrode. The upper electrode 5 is placed opposite the upper surface of the mount 4. The mount 4 and the upper electrode 5 form a pair of parallel-plate electrodes.

The electrostatic chuck 3 comprises a pad 7, a dielectric 8, and an electrode 9. The dielectric 8 that is a first member is made of an insulating material. The electrode 9 is embedded in the dielectric 8. The pad 7 that is a second member is a conductor. The pad 7 is placed on the dielectric 8.

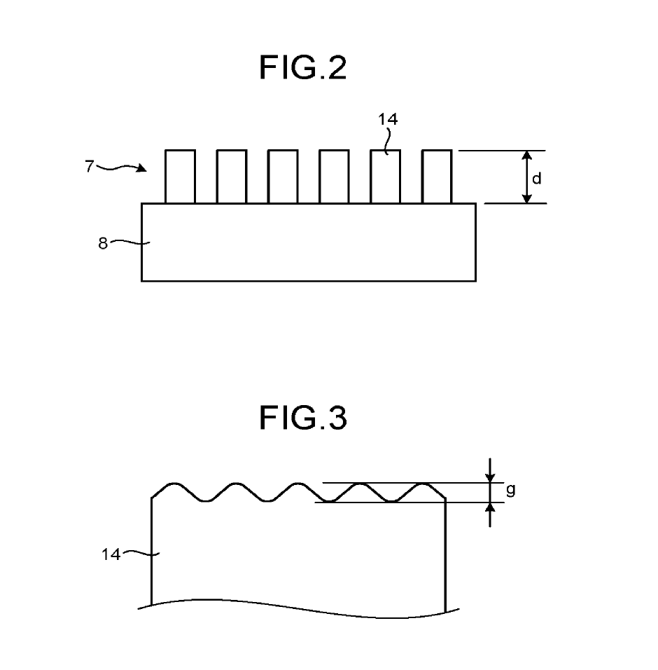

FIG. 2 is a side view showing schematically the configuration of the dielectric and the pad shown in FIG. 1. The pad 7 comprises multiple pillar-shaped bodies 14 made of a conductive material. The pillar-shaped bodies 14 are each in a pillar shape. The pillar-shaped bodies 14 are arranged in two-dimensional directions on the upper surface of the dielectric 8. The wafer 6 is mounted onto the pad 7.

The electrostatic chuck 3, a temperature measuring unit 11, a control unit 12, and a power supply 13 form an electrostatic chuck device as a mechanism for holding the wafer 6. The power supply 13 is a direct-current high voltage power supply to supply a voltage to the electrode 9.

The temperature measuring unit 11 measures the temperature inside the dielectric 8. The temperature measuring unit 11 outputs the temperature measuring result to the control unit 12. The control unit 12 controls the voltage supplied from the power supply 13 to the electrode 9 according to the measuring result from the temperature measuring unit 11.

Next, the outline of processing in the plasma processing apparatus 1 will be described. A wafer 6 transferred into the vacuum chamber 2 is mounted onto the pad 7. The power supply 13 supplies a voltage according to the control of the control unit 12 to the electrode 9. The voltage supply to the electrode 9 results in electrostatic force being generated between the electrode 9 and the wafer 6. The wafer 6 is attracted and stuck by the electrostatic force to the electrostatic chuck 3.

The plasma processing apparatus 1 draws a vacuum in the vacuum chamber 2. The plasma processing apparatus I supplies a process gas into the vacuum chamber 2 where a vacuum is created. The plasma processing apparatus 1 adjusts the flow rate of the process gas so that the inside of the vacuum chamber 2 is at a pressure at which electrical discharge can occur. The plasma processing apparatus 1 applies a high-frequency voltage to the mount 4 with the vacuum chamber 2 and the upper electrode 5 being grounded. By this means, the plasma processing apparatus 1 generates plasma in the vacuum chamber 2. The plasma processing apparatus 1 executes plasma processing on the wafer 6. After processing the wafer 6 finishes, the plasma processing apparatus 1 transfers the wafer 6 out of the vacuum chamber 2.

FIG. 3 is a diagram showing, in enlarged view, the upper surface and part adjacent thereto of the pillar-shaped body shown in FIG. 2. In FIG. 2, “d” indicates the thickness of the gad 7 that is the height of the pillar-shaped bodies 14. In FIG. 3, “g” denotes the surface roughness of the upper surface of the pillar-shaped body 14. Let the surface roughness be a parameter indicating an elevation difference between dents and bumps in the surface of the pillar-shaped body 14. The surface roughness is a parameter that may be defined according to any technique.

Attractive force (chuck force) P that attracts and sticks the wafer 6 to the pad 7 is expressed by the following equation (1).

P=α×(V/g)²+β×(V/D)² (1)

Here, “D” is the distance between the dielectric 8 and the wafer 6. If the wafer 6 is flat, the relation D=d holds. If a warp occurs in the wafer 6, the relation D=d holds for a position at which the wafer 6 touches a pillar-shaped body 14. For the other positions, the relation D>d holds. The “q” denotes the surface roughness of the upper surface of the pillar-shaped body 14. The “V” denotes the voltage applied to the electrode 9. The “α” and “β” are coefficients.

The plasma processing apparatus 1 performs transfer into the vacuum chamber 2, plasma processing, and transfer out of the vacuum chamber 2 on each wafer 6 subject to processing. On the electrostatic chuck 3, mounting a wafer 6 and lifting it up are repeated. When a wafer 6 is mounted onto the electrostatic chuck 3, and when the wafer 6 is taken up from the electrostatic chuck 3, the pad 7 suffers friction with the wafer 6.

The wafer 6 after processing is transferred out of the vacuum chamber 2, and then a new wafer 6 is transferred into the vacuum chamber 2. When the new wafer 6 is transferred in, the inside of the vacuum chamber 2 is kept at a high temperature since the preceding wafer 6 was processed. The new wafer 6 at room temperature is transferred into this high-temperature environment. After mounted onto the electrostatic chuck 3, the wafer 6 rapidly rises in temperature to expand. This expansion also causes the pad 7 to suffer friction with the wafer 6.

In this way, the pad 7 suffers friction with the wafer 6 each time a wafer 6 is processed in the plasma processing apparatus 1. As the number of wafers 6 processed in the plasma processing apparatus 1 increases, the wear of the pad 7 due to friction with wafers 6 progresses.

In the case where dents and bumps exist in the upper surface of the pillar-shaped body 14 as shown in FIG. 3, the wear of the pad 7 progresses at vertices of the bumps. As the wear of the pad 7 progresses, “g” gradually decreases. After dents and bumps in the upper surface of the pillar-shaped body 14 are flattened, and thus “g” becomes about zero, wear progresses over the entire upper surface of the pillar-shaped body 14. The “D” gradually decreases. As the wear of the pad 7 progresses in this way, the distance between the wafer 6 mounted on the electrostatic chuck 3 and the electrode 9 becomes shorter.

According to the above equation (1), decreases in “g” and “D” results in an increase in attractive force P. As “g” and “D” decrease, so that the distance between the wafer 6 and the electrode 9 becomes shorter, the attractive force exerted on the wafer 6 becomes stronger. Excessive attractive force being exerted on the wafer 6 may cause damage to the wafer 6. It may be difficult to take the wafer 6 up from the electrostatic chuck 3 because of excessive attractive force.

When a new wafer 6 transferred into the high-temperature environment is mounted onto the electrostatic chuck 3, heat transmission from the electrostatic chuck 3 at high temperature to the wafer 6 at low temperature occurs. Thus, the temperature of the electrostatic chuck 3 temporarily lowers. Stronger attractive force exerted on the wafer 6 promotes heat transmission from the electrostatic chuck 3 to the wafer 6 to a greater degree. The stronger the attractive force is, the greater the drop in the temperature of the electrostatic chuck 3 is.

The control unit 12 obtains the amount of change in the temperature of the dielectric 8 when a wafer 6 is mounted onto the electrostatic chuck 3 based on the measuring result from the temperature measuring unit 11. The amount of change in the temperature is an index for observing the strength of attractive force. The control unit 12 adjusts the voltage supplied to the electrode 9 according to the obtained amount of change. As wafers 6 sequentially mounted on the electrostatic chuck 3 are being processed, attractive force on the wafer 6 to the electrostatic chuck 3 varies. The control unit 12 reduces a change in attractive force associated with mounting wafers 6 onto the electrostatic chuck 3 and processing the wafers 6 by voltage adjustment. The temperature measuring unit 11 may obtain the amount of change in the temperature of the dielectric 8 when a wafer 6 is mounted onto the electrostatic chuck 3. The control unit 12 adjusts the voltage according to the amount of change obtained by the temperature measuring unit 11.

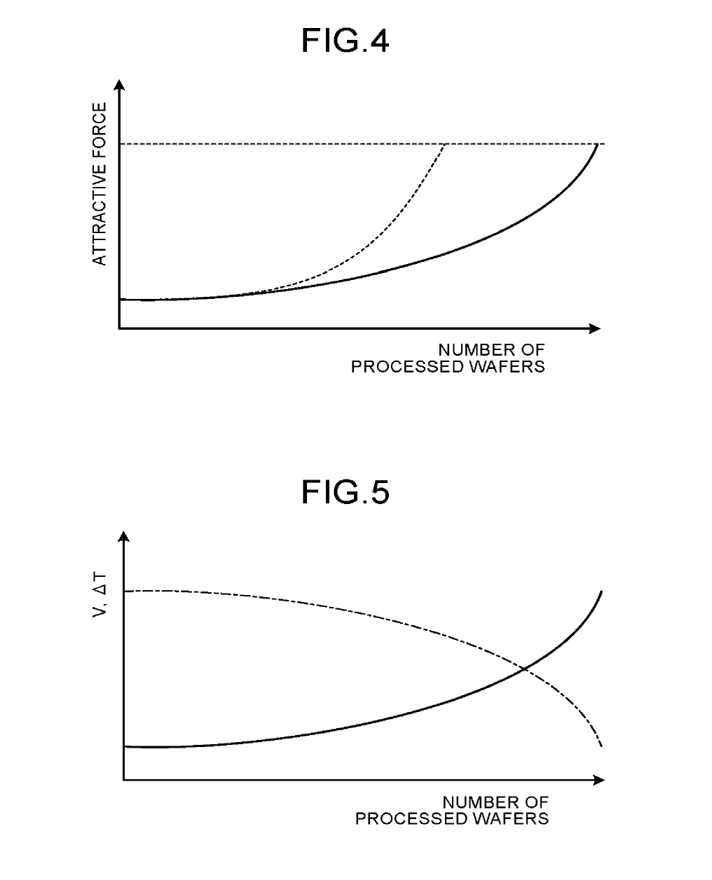

FIG. 4 is a graph showing the relation between the attractive force and the number of processed wafers in the first embodiment. The curve indicated by a broken line shows the relation in the case of a comparative example. The curve indicated by a solid line shows the relation in the case of the first embodiment.

In the comparative example, it is assumed that in the plasma processing apparatus 1 the power supply 13 supplies a constant voltage to the electrode 9. As the cumulative number of wafers 6 processed in the plasma processing apparatus 1 increases, the wear of the pad 7 progresses, so that the attractive force increases. Stronger attractive force causes the pad 7 to suffer a stronger force of friction with the wafer 6. Thus, as the number of processed wafers increases, the attractive force increases at an accelerated rate.

FIG. 5 is a graph showing the relation between the amount of change in the temperature and the number of processed wafers and the relation between the voltage and the number of processed wafers in the first embodiment. The curve indicated by a solid line shows the relation between the amount of change (ΔT) in the temperature and the number of processed wafers. The curve indicated by a dot-dashed line shows the relation between the voltage (V) supplied to the electrode 9 and the number of processed wafers.

The control unit 12 detects an increase in the amount of change in the temperature, thereby finding an increase in attractive force on the wafer 6. The control unit 12 decreases the voltage according to the increase in the amount of change in the temperature. By this means, the control unit 12 suppresses the increase in attractive force applied to the wafer 6.

The control unit 12 performs feedback control to adjust the voltage according to the result of obtaining the amount of change in the temperature. The control unit 12 adjusts the voltage, thereby making the amount of change in the temperature settle back to the level before the increase. The control unit 12 always or at an arbitrary frequency adjusts the voltage. The control unit 12 may perform feed-forward control to adjust the voltage so as to suppress the increase in the amount of change in the temperature. The control unit 12 reduces a change in the amount of change in the temperature associated with mounting wafers 6 onto the electrostatic chuck 3 and processing the wafers 6 by voltage adjustment.

The control unit 12 may acquire the relation between the number of processed wafers and the amount of change in the temperature beforehand to adjust the voltage according to the number of processed wafers. As the wear of the pad 7 progresses, the attractive force gradually increases. The greater the number of processed wafers, the greater also the increase in the amount of change in the temperature is. The control unit 12 decreases the voltage correspondingly as the number of processed wafers increases.

The plasma processing apparatus 1 can lessen accelerative increase in the attractive force agreeing with increase in the number of processed wafers by means of control by the control unit 12 in this way. Let the time when the attractive force reaches the level indicated by a broken straight line in FIG. 4 be a time at which to replace the electrostatic chuck 3. As shown in FIG. 4, in the first embodiment, the time at which to replace the electrostatic chuck 3 can be delayed as compared with the comparative example.

According to the first embodiment, the plasma processing apparatus 1 obtains the amount of change in the temperature of the electrostatic chuck 3 when a wafer 6 is mounted thereon. The control unit 12 reduces a change in the amount of change in the temperature by voltage adjustment. The control unit 12 reduces a change in attractive force on the wafer 6 to the electrostatic chuck 3 associated with mounting wafers 6 onto the electrostatic chuck 3 and processing the wafers 6 by voltage adjustment.

The plasma processing apparatus 1 delays increase in the attractive force due to increase in the number of processed wafers 6. The plasma processing apparatus 1 can delay the coming of the time at which to replace the electrostatic chuck 3. Thus, the plasma processing apparatus 1 produces the effect of being able to reduce the frequency of replacement of the electrostatic chuck 3. The plasma processing apparatus 1 can reduce the frequency of replacement of the electrostatic chuck 3, thus reducing operation cost. Further, the plasma processing apparatus 1 can suppress the occurrence of troubles due to excessive attractive force being exerted on wafers 6.

### Second Embodiment

A plasma processing apparatus 1 that is a semiconductor manufacturing apparatus of the second embodiment has the same configuration as the plasma processing apparatus 1 of the first embodiment. Duplicate description as in the first embodiment is omitted as needed.

In the second embodiment, the voltage is adjusted according to the results of measuring the distance between the dielectric 8 and the wafer 6 and the surface roughness of the upper surfaces of the pillar-shaped bodies 14. The distance and the surface roughness are indexes for observing the strength of attractive force. In the second embodiment, the temperature measuring unit 11 of the first embodiment may be omitted.

The distance (D) between the dielectric 8 and the wafer 6 and the surface roughness (g) of the pad 7 may be measured according to any technique. Actual measured data of “D” and “g” is inputted to the control unit 12. The height (d) of the pillar-shaped body 14 may be used as the distance between the dielectric 8 and the wafer 6. The control unit 12 performs feedback control to adjust the voltage according to the inputted data of the distance and the surface roughness. The control unit 12 decreases the voltage as the distance and the surface roughness become smaller. The control unit 12 may adjust the voltage at an arbitrary frequency.

According to the second embodiment, data of the distance between the dielectric 8 and the wafer 6 and the surface roughness of surface part of the pad 7 touching the wafer 6 is inputted to the control unit 12. The control unit 12 adjusts the voltage according to the distance between the dielectric 8 and the wafer 6 and the surface roughness of the pad 7. The control unit 12 can directly find out the progression degree of the wear of the pad 7 to adjust the voltage. Also in the second embodiment, the plasma processing apparatus 1 produces the effect of being able to reduce the frequency of replacement of the electrostatic chuck 3.

### Third Embodiment

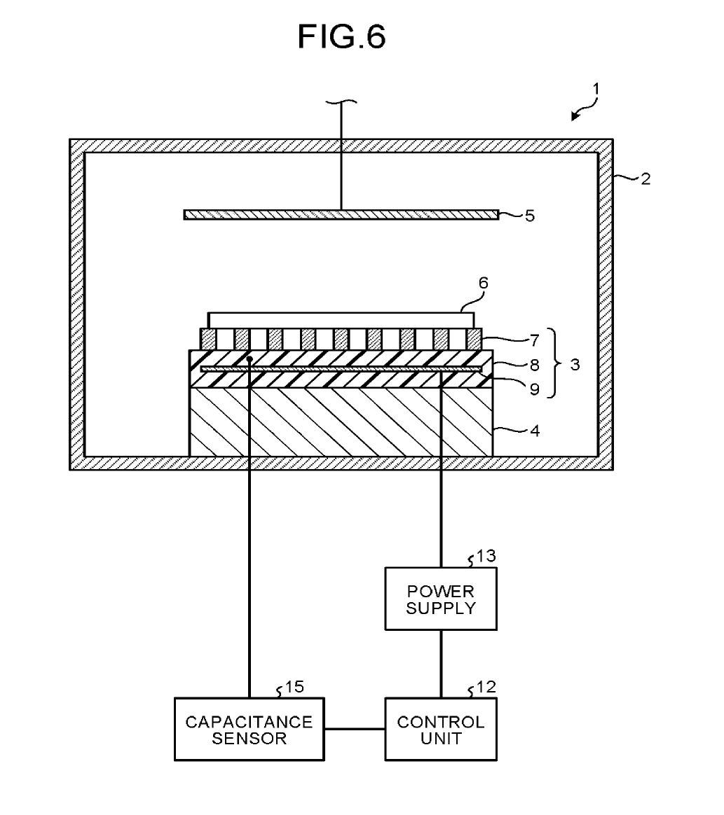

FIG. 6 is a diagram showing schematically the configuration of a semiconductor manufacturing apparatus of the third embodiment. A plasma processing apparatus 1 that is the semiconductor manufacturing apparatus comprises a capacitance sensor 15. The same reference numerals are used to denote the same parts as in the first embodiment previously described, with duplicate description thereof being omitted as needed.

The capacitance sensor 15 that is an electrostatic capacity measuring unit measures the capacitance between the electrostatic chuck 3 and the wafer 6. The capacitance sensor 15 outputs the measuring result to the control unit 12. The control unit 12 acquires the capacitance when a wafer 6 is mounted onto the electrostatic chuck 3. The capacitance is an index for observing the strength of attractive force. The control unit 12 performs feedback control to adjust the voltage according to the measured capacitance. The control unit 12 adjusts the voltage according to change in the capacitance associated with mounting wafers 6 onto the electrostatic chuck 3 and processing the wafers 6. The electrostatic chuck 3, the control unit 12, the power supply 13, and the capacitance sensor 15 form an electrostatic chuck device as a mechanism for holding a wafer 6.

As the wear of the pad 7 progresses, the distance (D) between the dielectric 8 and the wafer 6 and the surface roughness (g) of the upper surfaces of the pillar-shaped bodies 14 decrease. Since the distance between the wafer 6 and the electrode 9 becomes shorter, the capacitance measured by the capacitance sensor 15 becomes larger. As the capacitance becomes larger, the control unit 12 decreases the voltage. The control unit 12 may perform feed-forward control to adjust the voltage so as to suppress the increase in the capacitance. The control unit 12 reduces a change in the capacitance associated with mounting wafers 6 onto the electrostatic chuck 3 and processing the wafers 6 by voltage adjustment.

According to the third embodiment, the plasma processing apparatus 1 measures the capacitance between the electrostatic chuck 3 and the wafer 6. The control unit 12 reduces a change in the capacitance by voltage adjustment. The control unit 12 can find out the progression degree of the wear of the pad 7 to adjust the voltage. Also in the third embodiment, the plasma processing apparatus 1 produces the effect of being able to reduce the frequency of replacement of the electrostatic chuck 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, comprising:
an electrostatic chuck including an electrode to generate electrostatic force and onto which to mount a work attracted and stuck by the electrostatic force; and
a control unit that controls a voltage supplied to the electrode,
wherein the control unit adjusts the voltage according to change in attractive force on the work to the electrostatic chuck associated with mounting works onto the electrostatic chuck and processing the works.

2. The semiconductor manufacturing apparatus according to claim 1, further comprising:
a temperature measuring unit that measures a temperature of the electrostatic chuck,
wherein the control unit obtains an amount of change in the temperature of the electrostatic chuck when a work is mounted onto the electrostatic chuck and adjusts the voltage according to change in the amount of change in the temperature.

3. The semiconductor manufacturing apparatus according to claim 2, wherein the control unit performs feedback control to adjust the voltage according to a result of obtaining the amount of change in the temperature.

4. The semiconductor manufacturing apparatus according to claim 2, wherein the control unit perform feed-forward control to adjust the voltage so as to suppress increase in the amount of change in the temperature.

5. The semiconductor manufacturing apparatus according to claim 2, wherein the control unit acquires a relation between number of processed works and the amount of change in the temperature beforehand and adjusts the voltage according to the number of processed works.

6. The semiconductor manufacturing apparatus according to claim 1, wherein the electrostatic chuck comprises:
a first member that is a dielectric; and
a second member constituted by a conductor and placed on the first member, and
the control unit adjusts the voltage according to a result of measuring a distance between the work mounted on the second member and the first member.

7. The semiconductor manufacturing apparatus according to claim 6, wherein the control unit adjusts the voltage according to the result of measuring the distance and a result of measuring a surface roughness of a surface part of the second member, the surface part being touched the work.

8. The semiconductor manufacturing apparatus according to claim 7, wherein the control unit performs feedback control to adjust the voltage according to the distance and the surface roughness measured.

9. The semiconductor manufacturing apparatus according to claim 1, further comprising:
an electrostatic capacity measuring unit that measures a capacitance between the electrostatic chuck and the work,
wherein the control unit adjusts the voltage according to change in the capacitance.

10. A control method of an electrostatic chuck, comprising:
generating electrostatic force between a work mounted on the electrostatic chuck and an electrode provided in the electrostatic chuck by voltage supply to the electrode;
making the work be attracted and stuck to the electrostatic chuck by the electrostatic force; and
adjusting the voltage, thereby reducing a change in attractive force on the work to the electrostatic chuck associated with mounting works onto the electrostatic chuck and processing the works.

11. The control method of the electrostatic chuck according to claim 10, further comprising:
obtaining an amount of change in a temperature of the electrostatic chuck when a work is mounted onto the electrostatic chuck,
the voltage being adjusted to reduce a change in the amount of change in the temperature.

12. The control method of the electrostatic chuck according to claim 11, wherein feedback control to adjust the voltage is performed according to a result of obtaining the amount of change in the temperature.

13. The control method of the electrostatic chuck according to claim 11, wherein feed-forward control to adjust the voltage is performed so as to suppress increase in the amount of change in the temperature.

14. The control method of the electrostatic chuck according to claim 11, further comprising:
acquiring a relation between the number of processed works and the amount of change in the temperature beforehand,
the voltage being adjusted according to the number of processed works.

15. The control method of the electrostatic chuck according to claim 10, wherein the electrostatic chuck comprises:
a first member that is a dielectric; and
a second member constituted by a conductor and placed on the first member, and
the method further comprises measuring a distance between the work mounted on the second member and the first member, the voltage being adjusted according to a result of measuring the distance.

16. The control method of the electrostatic chuck according to claim 15, further comprising:
measuring a surface roughness of a surface part of the second member, the surface part being touched the work,
the voltage being adjusted according to the result of measuring the distance and a result of measuring the surface roughness.

17. The control method of the electrostatic chuck according to claim 16, wherein feedback control to adjust the voltage is performed according to the distance and the surface roughness measured.

18. The control method of the electrostatic chuck according to claim 10, further comprising:
measuring a capacitance between the electrostatic chuck and the work,
the voltage being adjusted to reduce a change in the capacitance.

19. An electrostatic chuck device comprising:
an electrostatic chuck including an electrode to generate electrostatic force and onto which to mount a work attracted by the electrostatic force; and
a temperature measuring unit that measures a temperature of the electrostatic chuck,
wherein a voltage supplied to the electrode is adjusted based on a result of measuring the temperature of the electrostatic chuck by the temperature measuring unit.

20. The electrostatic chuck device according to claim 19, wherein the temperature measuring unit is configured to obtain an amount of change in the temperature of the electrostatic chuck when a work is mounted onto the electrostatic chuck.
